(19) United States
(12) Patent Application Publication
(10) Pub. No.: US 2024/0155928 A1
(43) Pub. Date: May 9, 2024

(54) DISPLAY DEVICE

(71) Applicant: LG Display Co., Ltd., Seoul (KR)

(72) Inventor: Jae Gyu LEE, Paju-si (KR)

(21) Appl. No.: 18/503,958

(22) Filed: Nov. 7, 2023

(30) Foreign Application Priority Data
Nov. 9, 2022 (KR) 10-2022-0148701

(51) Int. Cl. H10K 59/80; H10K 59/90

(52) U.S. Cl. CPC H10K 59/8794; H10K 59/90; H10K 59/40

(57) ABSTRACT

A display device may include a plate, a display panel on the plate, at least one circuit chip connected to a side of the display panel, and a coated layer on at least one surface of the plate. The coated layer may include a first region overlapping the at least one circuit chip and a second region not overlapping the at least one circuit chip, and black concentration of the first region is different from black concentration of the second region.

### CROSS-REFERENCE TO RELATED APPLICATION(S)

This application claims the priority benefit of Korean Patent Application No. 10-2022-0148701, filed on Nov. 9, 2022, which is hereby incorporated by reference for all purposes as if fully set forth herein.

### BACKGROUND

### Technical Field

The present disclosure relates to a display device.

### Description of the Related Art

As society enters an information age in earnest, various display devices for processing and displaying a large amount of information have been developed. There are various types of display devices that display images, such as a liquid crystal display, an organic light-emitting display device, an electroluminescence display device, a field emission display (FED) device, a plasma display panel (PDP), and an electrophoretic display device, etc.

A range of applications of display devices is diversifying from computer monitors and TVs to personal portable devices, and research into a display device having a reduced volume and weight while having a large display area has been conducted.

In addition, recently, research into a flexible display device manufactured to be able to display an image even when the display device is bent like paper by forming display elements and wires on a flexible substrate such as plastic, which is a flexible material, has been actively conducted.

The description provided in the background section should not be assumed to be prior art merely because it is mentioned in or associated with the background section. The background section may include information that describes one or more aspects of the subject technology, and the description in this section does not limit the disclosure.

### BRIEF SUMMARY

The inventors have recognized problems described above and other limitations associated with the related art. Accordingly, the present disclosure is directed to a display device that substantially obviates one or more problems due to limitations and disadvantages of the related art.

In order to reduce a thickness of the display device, various studies have been conducted to reduce components of the display device. When a thickness of a component of the display device is reduced, warpage due to a difference in stress caused by temperature change of the display device is affected, and thus a problem occurs in performance of the display device.

Accordingly, the inventors of the present disclosure have recognized the above-mentioned problems, and conducted various experiments to improve warpage of the display device and to improve the performance of the display device. Through various experiments, a new display device capable of improving warpage of the display device and improving the performance of the display device has been invented.

A problem to be solved according to embodiments of the present disclosure is to provide a display device capable of improving reliability of a display device by improving warpage.

Problems to be solved according to the example embodiments of the present disclosure are not limited to the above-mentioned problem, and other problems not mentioned will be clearly understood by those skilled in the art from the description below.

Additional advantages, benefits and features of the disclosure will be set forth in part in the description which follows and in part will become apparent to those having ordinary skill in the art upon examination of the following or may be learned from practice of the disclosure. The benefits and other advantages of the disclosure may be realized and attained by the structure particularly pointed out in the written description and claims hereof as well as the appended drawings.

To achieve these benefits and other advantages and in accordance with the purpose of the disclosure, as embodied and broadly described herein, a display device includes a plate, a display panel provided on the plate, at least one circuit chip provided on one side of the display panel, and a coated layer on at least one surface of the plate. The coated layer includes a first region overlapping the at least one circuit chip and a second region at an edge of the plate, and black concentration of the first region is different from black concentration of the second region.

In another aspect of the present disclosure, a display device includes a plate, a display panel provided on the plate, and a coated layer on at least one surface of the plate, wherein the plate comprises a center region and an edge region, and black concentration of the coated layer located in the center region is different from black concentration of the coated layer located in the edge region.

In another aspect of the present disclosure, a display device includes a plate, a display panel provided on the plate, at least one circuit chip provided on one side of the display panel, and a coated layer on at least one surface of the plate, wherein the coated layer comprises a first region overlapping at least one circuit chip and a second region not overlapping the at least one circuit chip, and emissivity of the first region is different from emissivity of the second region.

In another aspect of the present disclosure, a display device includes a plate, a display panel on the plate and a coated layer on at least one surface of the plate. The plate includes a first region and a second region. Black concentration of the coated layer located in the first region is higher than black concentration of the coated layer located in the second region.

In another aspect of the present disclosure, a display device includes a plate, a display panel on a first side of the plate, a circuit chip connected to the display panel and positioned on a second side of the plate, and a resin layer on at least one surface of the plate. The resin layer includes a first region corresponding to the circuit chip and a second region adjacent the first region. The first region has emissivity that exceeds that of the second region.

Other details of the example embodiments are included in the detailed description and drawings.

It is to be understood that both the foregoing general description and the following detailed description of the present disclosure are examples and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a view illustrating a use example of a display device according to an example embodiment of the present disclosure;

FIG. 2 is an exploded perspective view illustrating the display device according to an example embodiment of the present disclosure;

FIG. 3 is a cross-sectional view illustrating the display device according to an example embodiment of the present disclosure;

FIG. 4 is a perspective view of the display device according to an example embodiment of the present disclosure;

FIG. 5 is a block diagram of the display device according to an example embodiment of the present disclosure;

FIG. 6 is a cross-sectional view taken along line I-I′ of FIG. 4 according to an example embodiment of the present disclosure;

FIG. 7 is a view for describing the display device according to an example embodiment of the present disclosure;

FIG. 8 is a view illustrating temperatures according to a comparative example of the present disclosure;

FIG. 9 is a plan view according to an example embodiment of the present disclosure;

FIG. 10 is a cross-sectional view according to an example embodiment of the present disclosure;

FIGS. 11, 12, and 13 are views illustrating processes according to an example embodiment of the present disclosure; and

FIG. 14 is a view illustrating temperatures according to an example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the technical concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The advantages and features of the present disclosure, and the method for achieving the advantages and features will become apparent with reference to embodiments described below in detail in conjunction with the accompanying drawings. However, the present disclosure is not limited to the embodiments disclosed below and may be implemented in a variety of different forms, and these embodiments allow the present disclosure to be complete and are provided to fully inform those of ordinary skill in the art to which the present disclosure belongs of the scope of the disclosure.

The shapes, sizes, areas, proportions, angles, numbers, etc., disclosed in the drawings for describing the example embodiments of the present disclosure are illustrative, and thus the present disclosure is not limited to the illustrated elements. The same reference symbols refer to the same elements throughout the specification. In addition, in describing the present disclosure, when it is determined that a detailed description of related known technology may unnecessarily obscure the subject matter of the present disclosure, a detailed description thereof will be omitted. When “including”, “having”, “consisting”, etc., are used in this specification, other parts may also be present, unless “only” is used. When an element is expressed in the singular, the case including the plural is included unless explicitly stated otherwise.

In interpreting an element, it is to be interpreted as including an error range even when there is no separate explicit description thereof. Any implementation described herein as an “example” is not necessarily to be construed as preferred or advantageous over other implementations.

In the case of a description of a positional relationship, for example, when a positional relationship between two parts is described using “on”, “above”, “below”, “next to”, etc., one or more other parts may be located between the two parts, unless “immediately” or “directly” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In the case of a description of a temporal relationship, when a temporal precedence relationship is described using “after”, “subsequent to”, “next”, “before”, etc., the case of a discontinuous relationship may be included, unless “immediately” or “directly” is used.

In describing the elements of the present disclosure, terms such as first, second, A, B, (a), and (b) may be used. These terms are only used to distinguish the element from other elements, and the nature, sequence, order, or number of the corresponding component is not limited by the term. When an element is described as being “coupled to,” “combined with,” or “connected to” another element, the element may be directly coupled or connected to the other element. However, it should be understood that another element may be “interposed” between respective elements indirectly connected or connectable to each other unless specifically stated otherwise.

“At least one” should be understood to include all combinations of one or more associated elements. For example, “at least one of a first, second, or third element” may not only mean the first, second, or third element, but also include a combination of all elements of two or more of the first, second, and third elements.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the present disclosure, a “display device” may include a display device in a narrow sense such as a liquid crystal module (LCM) including a display panel and a driving unit or driving circuit for driving the display panel, an organic light-emitting module (OLED module), or a quantum dot (QD) module. In addition, the “display device” may include a notebook computer, a television, a computer monitor, and an automotive display apparatus, each of which is a complete product or a final product including the LCM, the OLED module, the QD module, etc., or a set electronic apparatus or a set device (or set apparatus) such as an equipment display apparatus including another type of vehicle or a mobile electronic apparatus such as a smartphone or an electronic pad.

Therefore, the display device in the present disclosure may include a display device such as an LCM, an OLED module, or a QD module in a narrow sense, and include an application product including the LCM, the OLED module, or the QD module, or a set device, which is a final consumer device.

In some cases, the LCM, the OLED module, and the QD module, each of which includes the display panel and the driving unit, may be expressed as a “display device” in a narrow sense, and an electronic device as a finished product including the LCM, the OLED module, and the QD module may be separately expressed as a “set device.” For example, the display device in a narrow sense includes a liquid crystal (LCD), organic light-emitting (OLED), or QD display panel, and a source PCB that is a controller for driving the display panel, and the set device may further include a set PCB that is a set controller electrically connected to the source PCB to control the entire set device.

As a display panel used in the example embodiments of the present disclosure, it is possible to use all types of display panel such as a liquid crystal display panel, an OLED display panel, a QD display panel, and an electroluminescent display panel. The display panel of the present embodiment includes a flexible substrate for an OLED display panel and a support member support structure below, and is not limited to a specific display panel allowed to be bezel-bent. In addition, a shape or size of the display panel used in the display device according to the present disclosure is not limited.

For example, when the display panel is the OLED display panel, the display panel may include a plurality of gate lines and data lines, and pixels formed at regions of overlap of the gate lines and/or the data lines. The data line DL may be formed of a conductive material, for example, copper (Cu), aluminum (Al), molybdenum (Mo), nickel (Ni), titanium (Ti), chromium (Cr), or an alloy thereof, but is not limited thereto. Further, the display panel may include an array including a thin film transistor as an element for selectively applying a voltage to each pixel, a light-emitting element layer on the array, and an encapsulation substrate or an encapsulation layer disposed on the array to cover the light-emitting element layer. The encapsulation layer may protect the thin film transistor and the light-emitting element layer from external impact, and may prevent penetration of moisture or oxygen into the light-emitting element layer. In addition, the layer formed on the array may include an inorganic light-emitting layer, for example, a nanoscale material layer or QDs.

A size and a thickness of each component illustrated in the drawing are illustrated for convenience of description, and the present disclosure is not limited to the size and the thickness of the component illustrated.

Respective features of the various embodiments of the present disclosure may be partially or entirely combined or associated with each other, various forms of interlocking and driving are technically possible, and respective embodiments may be implemented independently of each other, or may be implemented in association with each other.

Hereinafter, the example embodiments of the present disclosure examined through the accompanying drawings and examples are as follows. Scales of elements illustrated in the drawings are different scales from actual ones for convenience of description, and thus are not limited to the scales illustrated in the drawings.

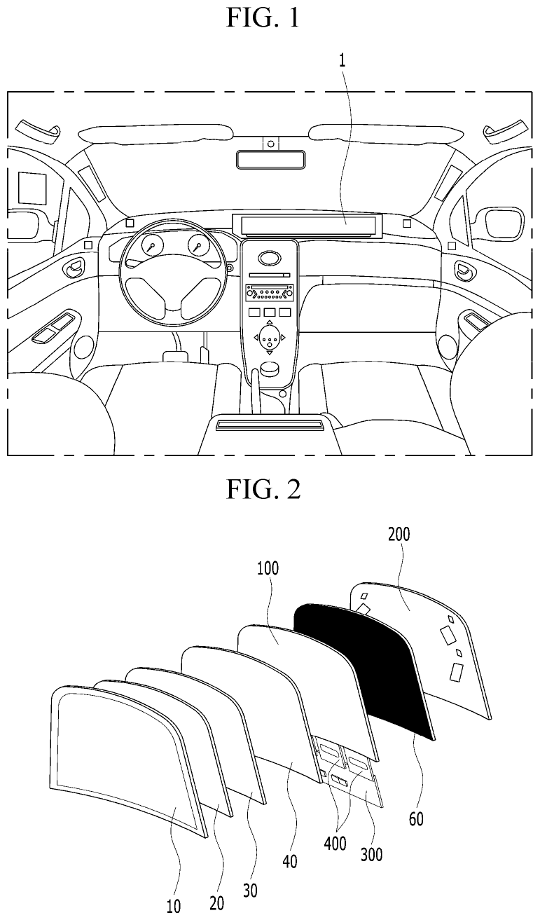

FIG. 1 is a view illustrating a use example of a display device according to an example embodiment of the present disclosure, in which, for example, the display device is provided inside a vehicle.

As illustrated in FIG. 1, the display device 1 may be disposed on, for example, at least a part of a dashboard of the vehicle. Embodiments are not limited thereto. As an example, the display device 1 may be disposed on a position separated from the dashboard of the vehicle. The dashboard of the vehicle has a configuration of being disposed in front of a front seat (for example, a driver's seat or a front passenger's seat) of the vehicle, without being limited thereto. For example, an input component for operating various functions (for example, an air conditioner, an audio system, and/or a navigation system) inside the vehicle may be disposed on the dashboard of the vehicle, without being limited thereto.

In the example embodiment, the display device 1 may be disposed on the dashboard of the vehicle to operate as an input unit or input device for operating at least some of various functions of the vehicle. The display device 1 may provide various information, such as various information related to the vehicle, for example, driving information of the vehicle (for example, a current speed of the vehicle, a remaining fuel amount, and/or a range), and information on parts of the vehicle (for example, a degree of damage to a vehicle tire).

In the example embodiment, the display device 1 may be disposed across the driver's seat and the front passenger's seat disposed in front seats of the vehicle, without being limited thereto. Users of the display device 1 may include a driver of the vehicle and/or a passenger sitting in the passenger' seat. Both the driver and the passenger of the vehicle may use the display device 1, without being limited thereto. As an example, the display device 1 may be disposed to correspond to only one of the driver's seat and the front passenger's seat. As an example, only one of the driver and the passenger of the vehicle may use the display device 1.

In the example embodiment, the display device 1 illustrated in FIG. 1 may be only partially illustrated. The display device 1 illustrated in FIG. 1 may represent a display panel among various components included in the display device 1. As an example, at least one of components of the display device 1 other than those illustrated in FIG. 1 may be mounted inside (or be part of) the vehicle. All the components of each display device according to all embodiments of the present disclosure may be operatively coupled and configured.

The display device mounted in the vehicle is an example for describing the present disclosure, and the example embodiment of the present disclosure is not limited thereto.

FIG. 2 is an exploded perspective view illustrating the display device according to the example embodiment of the present disclosure.

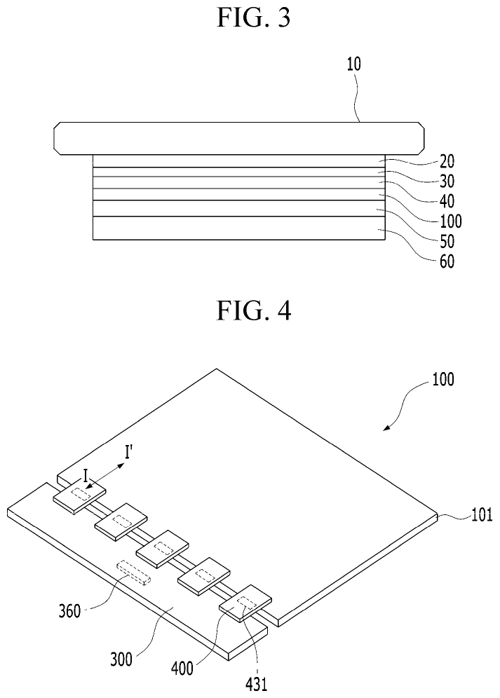

FIG. 3 is a cross-sectional view illustrating the display device according to the example embodiment of the present disclosure.

For example, the display device according to the example embodiment of the present disclosure may be mounted in a cockpit of the vehicle to provide an image, video and/or other information, (e.g., image, video and/or other information beneficial for driving) to the driver and the passenger of the vehicle. However, the display device is not limited thereto, and may be used while being carried by the user without being mounted in the vehicle. Hereinafter, for example, the display device mounted in the vehicle will be described. The display device mounted in the vehicle is an example for describing the present disclosure, and the example embodiments of the present disclosure are not limited thereto.

Referring to FIGS. 2 and 3, the display device according to the example embodiment of the present disclosure may include a display panel 100, and a plate 60, a printed circuit board 300 and a flexible circuit film 400 (chip on film, COF), which, for example, may be disposed on a rear surface side of the display panel 100. The printed circuit board 300 and the flexible circuit film 400 may be electrically connected to the display panel 100. At least one of the plate 60, the printed circuit board 300 and the flexible circuit film 400 may be omitted, according to the design of the display device.

An image, video and/or other information may be reproduced on the display panel 100. The reproduced image or video may be navigation information, an image, (for example, an image captured by a camera, for example, installed in the vehicle), or various other content. As an example, the reproduced image, video and/or other information may be beneficial for the driver or the passenger.

A guide panel 200 may be optionally disposed behind the display panel 100. The guide panel 200 may be disposed on a rearmost side of the display device. Various parts of the display device including the display panel 100 may be mounted on the guide panel 200. In addition, the guide panel 200 may be mounted on the cockpit of the vehicle, and to this end, the guide panel 200 may be provided with a coupling structure such as a screw hole, without being limited thereto.

The printed circuit board 300 may be electrically connected to the display panel 100. As an example, the printed circuit board 300 may include a device for communicating with an external device such as a camera or a main control module of the vehicle. A device for driving the display panel 100 so that the display panel 100 reproduces the image or video, etc., may be provided, for example, by using a circuit of the display panel 100, the printed circuit board 300, the flexible circuit film 400 and/or the external device, and may include various other active elements and passive elements.

A side of the flexible circuit film 400 may be electrically connected to the display panel 100, and the other side thereof may be electrically connected to the printed circuit board 300. A part of the flexible circuit film 400 may be bent. As an example, a part of the flexible circuit film 400 may be bent so as to surround or wrap around (fully or partially) the guide panel 200. FIG. 2 illustrates a state in which the flexible circuit film 400 is unfolded.

The flexible circuit film 400 may be formed as a thin film and formed using a flexible material so as to be bent. The flexible circuit film 400 may electrically connect the display panel 100 and the printed circuit board 300 to each other. Various types of active elements and/or passive elements may be provided on the flexible circuit film 400, and/or a driving circuit for driving the display panel 100 may be provided thereon.

The driving circuit for driving the display panel 100 may be provided to be distributed to each of the printed circuit board 300 and the flexible circuit film 400, without being limited thereto. A driving chip forming at least a part of the driving circuit of the display panel 100 may be provided on the flexible circuit film 400. A plurality of flexible circuit films 400 may be provided. The plurality of flexible circuit films 400 may be disposed to be spaced apart from each other.

The display device according to the present disclosure may further optionally include a cover member 10, a first adhesive layer 20, a functional film 30, and a second adhesive layer 40, which are sequentially disposed on an upper side of the display panel 100. A support member 50 and a plate 60 may be optionally included as support structures on a lower side of the display panel 100. Components included in the display device may be formed thin to manufacture a slim display panel. At least one of the above-mentioned components may be omitted according to the design of the display device.

The cover member 10 may be disposed in front of the display panel 100 to protect the display panel 100. The cover member 10 is formed of a transparent material so that light emitted from the cover member 10 can pass through the cover member 10.

The functional film 30 may include a wide-angle adjusting structure to adjust a viewing range of an image displayed on the display panel 100. As an example, the wide-angle adjusting structure may be a trapezoidal pattern when viewed in a cross section, an angle of which is adjusted to fit a desired viewing angle, and the wide-angle adjusting structure may be provided in the functional film 30. The trapezoidal pattern may be formed of a light blocking material, and embodiments of the present disclosure are not limited thereto. In addition, the functional film may include a polarizer, etc., that controls display characteristics (for example, external light reflection, color accuracy, luminance, etc.). In some cases, the functional film 30 may be included as a pattern on an uppermost side of the display panel 100 or on an inner surface of the cover member 10 without being separately formed, or may not be included. The example embodiments of the present disclosure are not limited thereto. The first adhesive layer 20 may be disposed between the cover member 10 and the functional film 30. The first adhesive layer 20 has one surface attached to the cover member 10, and the other surface attached to the functional film 30 so that the functional film 30 may be attached to the cover member 10.

The second adhesive layer 40 may be disposed between the functional film 30 and the display panel 100. The second adhesive layer 40 has a surface attached to the functional film 30, and the other surface attached to the display panel 100 so that the functional film 30 may be attached to the display panel 100.

The first adhesive layer 20 and the second adhesive layer 40 may be made of a transparent material having excellent adhesive strength, for example, an optically clear adhesive (OCA). The embodiments of the present disclosure are not limited thereto.

The support member 50 may be disposed behind the display panel 100. The support member 50 may be attached to the rear surface of the display panel 100 to reduce or prevent the display panel 100 from being bent and/or damaged. For example, the support member 50 may reinforce rigidity of the display panel 100.

The support member 50 may be provided as, for example, a film and attached to the display panel 100. However, the present disclosure is not limited thereto.

The support member 50 may be attached to a surface (second surface) opposite to a surface (first surface) emitting light among both surfaces of a substrate of the display panel 100. As an example, the support member 50 may be formed as a thin film including a combination of polyethylene naphthalate (PEN), polyethylene terephthalate (PET), polyethylene ether phthalate, polycarbonate, polyarylate, polyether imide, polyether sulfonate, polyimide, polyacrylate, or suitable polymers. The other suitable materials available for formation of the support member 50 may be thin glass, metal foil shielded using a dielectric, a multilayer polymer, a polymer film including a polymer material combined with nanoparticles or microparticles, etc. The support member 50 may be thicker than the substrate of the display panel 100 for support. The embodiments of the present disclosure are not limited thereto.

When the support member 50 is included, a process of fastening with the plate 60 may be performed after attaching the rear surface of the display panel 100 to the support member 50. The embodiments of the present disclosure are not limited thereto.

The plate 60 may be disposed behind the support member 50 and disposed in front of the guide panel 200. The plate 60 may be disposed to be in contact with a rear surface of the support member 50 and, for example, may further serve as a heat dissipating plate that cools the display panel 100 by dissipating heat generated from the display panel 100 to the outside.

The plate 60 may be made of a material that is easy to manufacture through sheet metal processing, has a high heat transfer rate, and/or has excellent resistance, for example, aluminum. The embodiments of the present disclosure are not limited thereto.

FIG. 4 is a perspective view of the display device according to the example embodiment of the present disclosure.

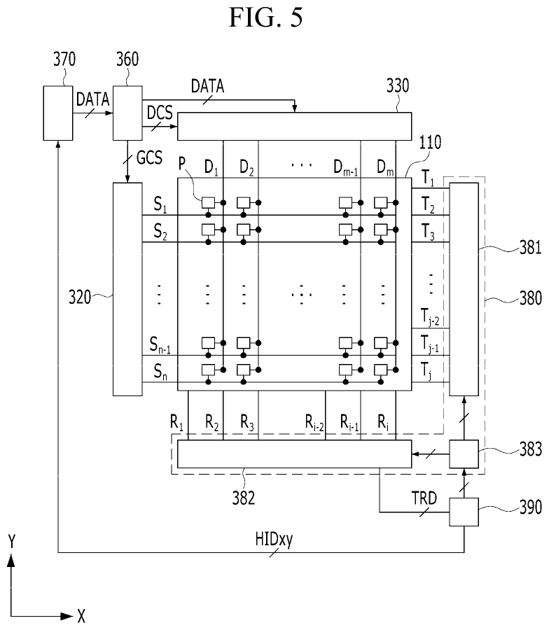

FIG. 5 is a block diagram of the display device according to the example embodiment of the present disclosure.

Referring to FIGS. 4 and 5, the display device 1 according to the example embodiment of the present disclosure includes the display panel 100, a scan driver 320, a data driver 330, a timing controller 360, a host system 370, a touch driver 380, and a touch coordinate calculator 390, without being limited thereto. At least one of the above-mentioned components may be omitted or integrated with other components.

In the present disclosure, implementing the display device as an organic light-emitting display (OLED) is described as an example. However, the present disclosure is not limited thereto, and the display device may be implemented as various display devices such as a liquid crystal display (LCD), a LED display, a Mini-LED display, an electrophoresis display, etc.

The display panel 100 may include a substrate 101 and a thin film transistor layer, a light-emitting element layer, an encapsulation layer, and, optionally, a touch sensing layer, which are disposed on the substrate 101, and the embodiments of the present disclosure are not limited thereto.

The display panel 100 includes an active area, which is an area in which a plurality of pixels is provided to display an image. Data lines (D₁ to Dₘ, where m is a positive integer greater than or equal to 2) and scan lines (S₁ to Sₙ, where n is a positive integer greater than or equal to 2) are formed on the display panel 100. The data lines D₁ to Dₘ may be formed to cross the scan lines S₁ to Sₙ. The scan lines may be gate lines. The pixels may be formed in areas where the scan lines and the data lines overlap each other.

Each of the pixels of the display panel 100 may be connected to one of the data lines D₁ to Dₘ and one of the scan lines S₁ to Sₙ, without being limited thereto.

Each of the pixels of the display panel 100 may include a driving transistor configured to adjust a drain-source current according to a data voltage applied to a gate electrode, a scan transistor turned on by a scan signal of a scan line to supply a data voltage of a data line to the gate electrode of the driving transistor, an organic light-emitting diode configured to emit light according to the drain-source current of the driving transistor, and a capacitor configured to store a voltage of the gate electrode of the driving transistor. Accordingly, each of the pixels may emit light according to a current supplied to the organic light-emitting diode.

The scan driver 320 receives a scan control signal GCS from the timing controller 360. The scan driver 320 supplies scan signals to the scan lines Si to S r, according to the scan control signal GCS.

The scan driver 320 may be formed in a non-active area outside a side or both sides of the active area or in the vicinity of the active area AA of the display panel 100 in a gate driver in panel (GIP) type. Alternatively, the scan driver 320 may be manufactured as a driving chip, for example, at least one circuit chip 431, so that the scan driver 320 is mounted on the flexible circuit film 400, and the flexible circuit film 400 is attached to the non-active area outside a side or both sides of the active area of the display panel 100 in a tape automated bonding (TAB) type. The at least one circuit chip 431 may be disposed on one side of the display panel. Embodiments are not limited thereto. As an example, the gate driver may also be connected to the display panel 100 by a chip-on-glass (COG) method.

The data driver 330 receives digital video data DATA and a data control signal DCS from the timing controller 360. The data driver 330 converts the digital video data DATA into analog positive/negative polarity data voltages according to the data control signal DCS and supplies the data voltages to the data lines. For example, pixels to which the data voltages are to be supplied are selected by scan signals of the scan driver 320, and the data voltages are supplied to the selected pixels.

The data driver 330 may include the at least one circuit chip 431 as illustrated in FIG. 4. The at least one circuit chip 431 may be a source driver integrated circuit (IC). Each of the at least one circuit chip 431 may be mounted on the flexible circuit film 400 in a chip on film (COF) or chip on plastic (COP) type. The flexible circuit film 400 is attached to pads provided in the non-active area of the display panel 100, for example, using an anisotropic conductive film, whereby the at least one circuit chip 431 may be connected to the pads. Embodiments are not limited thereto. As another example, the gate driver 330 may be formed in the non-active area of the display panel 100 in a gate driver in panel (GIP) type, or may also be connected to the display panel 100 by a chip-on-glass (COG) method.

The printed circuit board 300 may be attached to the flexible circuit films 400. A plurality of circuits implemented as driving chips may be mounted on the printed circuit board 300. For example, the timing controller 360 may be mounted on the printed circuit board 300. The printed circuit board 300 may be a flexible or a non-flexible printed circuit board.

The timing controller 360 receives digital video data DATA and timing signals, for example, from the host system 370. The timing signals may include a vertical synchronization signal, a horizontal synchronization signal, a data enable signal, a dot clock, etc. The vertical synchronization signal is a signal that defines or includes one frame period. The horizontal synchronization signal is a signal that defines or includes one horizontal period beneficial to supply data voltages to pixels of one horizontal line of a display panel. The data enable signal is a signal that defines or includes a period in which valid data is input. The dot clock is a signal repeated at a predetermined or selected short cycle.

The timing controller 360 generates a data control signal DCS for controlling operation timing of the data driver 330 and a scan control signal GCS for controlling operation timing of the scan driver 320 based on the timing signals to control the operation timing of the scan driver 320 and the data driver 330. The timing controller 360 outputs the scan control signal GCS to the scan driver 320 and outputs the digital video data DATA and the data control signal DCS to the data driver 330.

The host system 370 may be implemented as a navigation system, a set-top box, a DVD player, a Blu-ray player, a personal computer (PC), a home theater system, a broadcast receiver, a phone system, etc. The host system 370 may include a System on Chip (SoC) incorporating a scaler to convert digital video data DATA of an input image into a format suitable for display on the display panel 100, without being limited thereto. The host system 370 transmits digital video data DATA and timing signals to the timing controller 360.

In addition to the data lines D₁ to Dₘ and the scan lines S₁ to Sₙ, first and second touch electrodes may be optionally formed on the display panel 100. The first touch electrodes may be formed to cross the second touch electrodes. The first touch electrodes may be connected to a first touch driver 381 through first touch lines T1, T2, T3, Tj−2, Tj−1, Tj, where j is a positive integer greater than or equal to 2. The second touch electrodes may be connected to a second touch driver 382 through second touch lines R1 to Ri, where i is a positive integer greater than or equal to 2. A touch sensor may be formed at each region of overlap of the first touch electrodes and the second touch electrodes. The embodiments of the present disclosure are not limited thereto. As an example, the first touch electrodes and the second touch electrodes may be connected to a single one touch driver.

The touch driver 380 supplies driving pulses to the first touch electrodes through the first touch lines T1 to Tj and senses the amount of change in charges of each touch sensor through the second touch lines R1 to Ri, without being limited thereto. Referring to FIG. 5, as an example, it has been described that the first touch lines T1 to Tj are Tx lines configured to supply driving pulses, and the second touch lines R1 to Ri are Rx lines configured to sense the amount of change in charges of each of the touch sensors. But embodiments are not limited thereto. As another example, the second touch lines R1 to Ri may be Tx lines configured to supply driving pulses, and the first touch lines T1 to Tj May be Rx lines configured to sense the amount of change in charges of each of the touch sensors. As another example, a self-capacitance structure may also be possible.

The touch driver 380 includes the first touch driver 381, the second touch driver 382, and a touch controller 183. The first touch driver 381, the second touch driver 382, and the touch controller 183 may be integrated into one read-out IC (ROIC).

The first touch driver 381 selects a first touch line to output a driving pulse under the control of the touch controller 183 and supplies the driving pulse to the selected first touch line. For example, the first touch driver 381 may sequentially or selectively supply driving pulses to the first touch lines T1 to Tj.

The second touch driver 382 selects second touch lines to receive the amounts of change in charges of the touch sensors under the control of the touch controller 183, and receives the amounts of change in charges of the touch sensors through the selected second touch lines. The second touch driver 382 samples the amounts of change in charges of the touch sensors received through the second touch lines R1 to Ri and converts the amounts into digital touch raw data TRD.

The touch controller 183 may generate a Tx setup signal for setting a first touch line to output a driving pulse in the first touch driver 381, and a Rx setup signal for setting a second touch line to receive a touch sensor voltage in the second touch driver 382. In addition, the touch controller 183 generates timing control signals for controlling operation timings of the first touch driver 381 and the second touch driver 382.

The touch coordinate calculator 390 receives input of touch row data TRD from the touch driver 380. The touch coordinate calculator 390 calculates touch coordinate(s) according to a touch coordinate calculation method, and outputs touch coordinate data HIDxy including information of the touch coordinate(s) to the host system 370.

The touch coordinate calculator 390 may be implemented as a micro-controller unit (MCU), without being limited thereto. The host system 370 analyzes the touch coordinate data HIDxy input from the touch coordinate calculator 390 and executes an application program associated with coordinates touched by a user. As an example, the host system 370 transmits the digital video data DATA and timing signals to the timing controller 360 according to the executed application program.

The touch driver 380 may be included in the circuit chips 431 or manufactured as a separate driver chip and, for example, may be mounted on the printed circuit board 300. In addition, the touch coordinate calculator 390 may be manufactured as a driving chip and, for example, may be mounted on the printed circuit board 300.

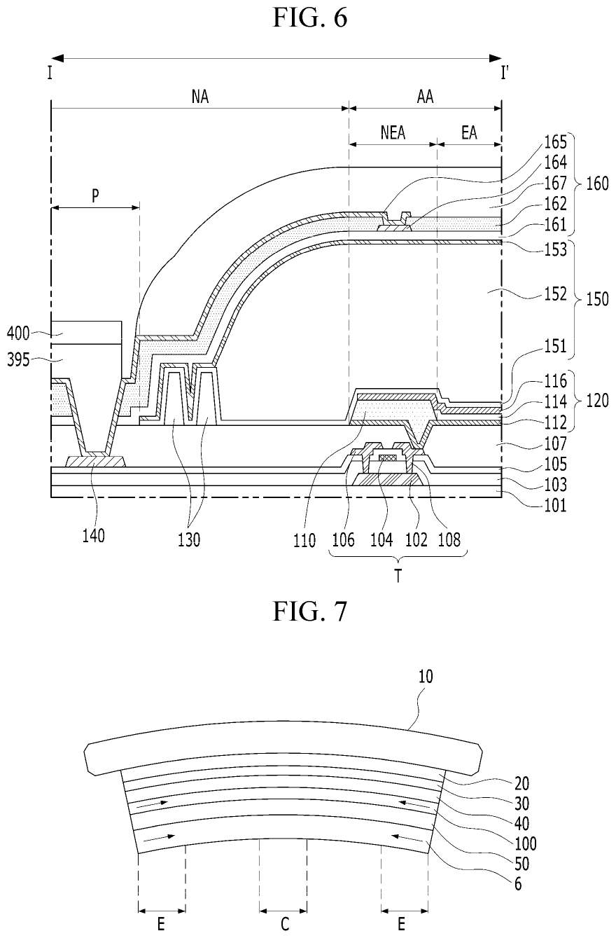

FIG. 6 is a cross-sectional view taken along line I-I′ of FIG. 4 according to an example embodiment of the present disclosure.

Referring to FIG. 6, the display panel 100 of the display device 1 according to the example embodiment of the present disclosure includes the substrate 101, a thin film transistor T, a planarization layer 107, a light-emitting element 120, a bank 110, a pad portion 140, a dam 130, an encapsulation portion 150, and a touch portion 160, without being limited thereto. As an example, at least one of the above-mentioned components may be omitted according to the design of the display device. The substrate 101 may include glass, plastic, or a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC) film, polyvinyl alcohol (PVA) film, and polystyrene (PS), and the present disclosure is not limited thereto.

The thin film transistor T is disposed on the substrate 101. The thin film transistor T transfers data voltages to a plurality of sub-pixels.

The substrate 101 supports various components of the display panel 100. The substrate 101 may be formed of an insulating material, for example, an opaque insulating material such as metal foil or a transparent insulating material such as glass or plastic, without being limited thereto. When the substrate 101 is made of plastic, the substrate 101 may be referred to as a plastic film or a plastic substrate. For example, the substrate 101 may be formed as a film including one of a polyimide-based polymer, a polyester-based polymer, a silicone-based polymer, an acrylic-based polymer, a polyolefin-based polymer, and the like, and a copolymer thereof. Among these materials, polyimide may be applied to a high-temperature process and used for coating, and thus is widely used as a plastic substrate. An array substrate is a concept including an element and a functional layer formed on the substrate 101, for example, a switching TFT, a driving TFT connected to the switching TFT, the light-emitting element 120 connected to the driving TFT, the encapsulation portion 150, etc.

A buffer layer may be optionally located on the substrate 101. The buffer layer is a functional layer for protecting the thin film transistor T from impurities such as alkali ions flowing out from the substrate 101 or lower layers. The buffer layer may be formed of silicon oxide (SiOx), silicon nitride (SiNx), or a multilayer thereof, and the embodiments of the present disclosure are not limited thereto.

The thin film transistor T may be disposed on the substrate 101 or the buffer layer. The thin film transistor T may include an active layer 102, a gate insulating layer 103, a gate electrode 104, an interlayer insulating layer 105, a source electrode 106, and a drain electrode 108. The active layer 102 is located on the substrate 101 or the buffer layer. The active layer 102 may be made of polysilicon (p-Si), and in this case, a predetermined or selected region may be doped with impurities. Alternatively, the active layer 102 may be made of amorphous silicon (a-Si) or various organic semiconductor materials such as pentacene. Alternatively, the active layer 102 may be made of an oxide semiconductor material or other semiconductor materials such as compound semiconductor materials.

Depending on the structure of the thin film transistor T, the gate electrode 104 may be disposed on or below the active layer 102. The gate electrode 104 may be made of various conductive materials such as magnesium (Mg), aluminum (Al), nickel (Ni), chromium (Cr), molybdenum (Mo), tungsten (W), gold (Au), or an alloy thereof. The embodiments of the present disclosure are not limited thereto.

The gate insulating layer 103 may be disposed between the active layer 102 and the gate electrode 104. The gate insulating layer 103 is a layer for insulating the gate electrode 104 and the active layer 102 and may be made of an insulating material. For example, the gate insulating layer 103 may include a single layer or multiple layers of silicon oxide (SiOx), silicon nitride (SiNx), Silicon oxynitride (SiOxNy), etc. However, the present disclosure is not limited thereto.

The source electrode 106 and the drain electrode 108 electrically connected to the active layer 102 and spaced apart from each other may be disposed on the interlayer insulating layer 105. The source electrode 106 and the drain electrode 108 may be made of a conductive material such as copper (Cu), aluminum (Al), molybdenum (Mo), titanium (Ti), or an alloy thereof. However, the present disclosure is not limited thereto.

Depending on the structure of the thin film transistor T, in order to insulate the gate electrode 104 from the source electrode 106 and the drain electrode 108, the interlayer insulating layer 105, etc., may be further disposed between the gate electrode 104 and the source electrode 106 (and the drain electrode 108). However, the present disclosure is not limited thereto.

The planarization layer 107 may be positioned on the thin film transistor T. The planarization layer 107 protects the thin film transistor T and/or planarizes a top of the thin film transistor T. The planarization layer 107 may be disposed in the active area AA, and the planarization layer 107 may not be disposed in all or part of the non-active area NA. The planarization layer 107 may be configured in various forms. The planarization layer 107 may be formed of an organic insulating film such as benzocyclobutene (BCB) or acrylic, or an inorganic insulating film such as silicon nitride (SiNx), silicon oxide (SiOx) or Silicon oxynitride (SiNxOy), etc., may be formed as a single layer, or may be modified in various forms such as double or multiple layers. The embodiments of the present disclosure are not limited thereto. The planarization layer 107 may include a contact hole CH for electrically connecting the thin film transistor T and the light-emitting element 120 to each other.

The light-emitting element 120 is disposed on the planarization layer 107. The light-emitting element is a self-emitting element configured to emit light, and may be driven by receiving voltage from a transistor, etc. The light-emitting element 120 may include a first electrode 112, a light-emitting layer 114 and a second electrode 116.

For example, the light-emitting element 120 may include the first electrode 112 formed on the planarization layer 107, the light-emitting layer 114 positioned on the first electrode 112, and the second electrode 116 positioned on the light-emitting layer 114. For example, the light-emitting element 120 is a self-emitting element configured to emit light, and may be driven by receiving voltage from the thin film transistor T, etc.

The first electrode 112 is electrically connected to the drain electrode 108 of the thin film transistor T which may be a driving thin film transistor through a contact hole CH. The first electrode 112 may be made of a conductive material capable of supplying holes to the light-emitting layer 114. When the display panel 100 is a top emission type, the first electrode 112 may be made of an opaque conductive material having high reflectance. For example, the first electrode 112 may be formed of silver (Ag), aluminum (Al), gold (Au), molybdenum (Mo), tungsten (W), chromium (Cr), an alloy thereof, etc. Alternatively, when the display panel 100 is a bottom emission type, the first electrode 112 may be made of a transparent conductive material, such as indium tin oxide (ITO) and indium zinc oxide (IZO). The embodiments of the present disclosure are not limited thereto.

The bank 110 is disposed on the first electrode 112 and the planarization layer 107. The bank 110 is an insulating layer for separating sub-pixels adjacent to each other. The bank 110 may be disposed to expose a part of the first electrode 112, and the bank 110 may be an organic insulating material disposed to cover an edge of the first electrode 112, without being limited thereto.

The bank 110 is formed in an area other than an emission area EA. Thus, the bank 110 may have a bank hole exposing the first electrode 112 corresponding to the emission area EA. The bank 110 may be made of an inorganic insulating material such as silicon nitride (SiNx) or silicon oxide (SiOx) or an organic insulating material such as BCB, acrylic resin, or imide resin.

The light-emitting layer 114 is disposed on the first electrode 112 exposed by the bank 110. The light-emitting layer 114 may include a light-emitting layer, an electron injection layer, an electron transport layer, a hole transport layer, a hole injection layer, etc., without being limited thereto. As an example, at least one of the electron injection layer, the electron transport layer, the hole transport layer, and the hole injection layer may be omitted. The light-emitting layer may be configured in a single light-emitting layer structure that emits one color of light, or may be configured in a structure including a plurality of light-emitting layers, for example, to emit white light by mixing light rays emitted from the plurality of light-emitting layers.

FIG. 6 illustrates that the light-emitting layer 114 disposed on each sub-pixel is separately disposed for each sub-pixel. However, the present disclosure is not limited thereto. For example, all or part of the light-emitting layer 114 may be formed as a single layer over a plurality of sub-pixels.

The second electrode 116 may be disposed on the light-emitting layer 114. The second electrode 116 is made of a conductive material capable of supplying electrons to the light-emitting layer 114. For example, the second electrode 116 may be made of a transparent conductive oxide based on indium tin zinc oxide (ITZO), zinc oxide (ZnO) and tin oxide (TO), or an ytterbium (Yb) alloy, and the embodiments of the present disclosure are not limited thereto. As an example, the second electrode 116 may be made of a significantly thin metal material. However, the present disclosure is not limited thereto. When the display panel 100 is a top emission type, the second electrode 116 may be made of a transparent conductive material such as indium tin oxide (ITO) or indium zinc oxide (IZO), or a reflective-transmissive metal alloy such as a MgAg alloy, so that light generated in the light-emitting layer 114 may pass through the second electrode 116.

FIG. 6 illustrates that second electrodes 116 disposed in the respective sub-pixels are connected to each other. However, the second electrode 116 may be separately disposed for each sub-pixel as the first electrode 112, and the present disclosure is not limited thereto.

The light-emitting layer 114 may be an organic light-emitting layer made of an organic material. However, the present disclosure is not limited thereto. For example, the light-emitting layer 114 may be an inorganic light-emitting layer including an inorganic semiconductor layer such as a quantum dot material or a mixed organic-inorganic light-emitting layer. In some cases, the light-emitting layer 114 may have an arrangement of micro-LEDs.

The active area AA may include a plurality of emission areas EA and a non-emission area NEA between the plurality of emission areas EA.

Areas in which a plurality of light-emitting elements 120 is disposed, respectively, may be the plurality of emission areas EA. Each of the plurality of emission areas EA is an area capable of independently emitting light of one color. The plurality of the emission areas EA may be areas corresponding to a plurality of the sub-pixels or an area in which the bank 110 is not disposed. For example, the plurality of emission areas EA may include a red emission area, a green emission area, and a blue emission area. However, the present disclosure is not limited thereto. As an example, the plurality of emission areas EA may further include a white emission area. As another example, the plurality of emission areas EA may include emission areas emitting light of other colors. The plurality of emission areas EA may be spaced apart from each other. For example, the areas may be disposed in a lattice form in which the areas are arranged in a row direction and a column direction. However, the present disclosure is not limited thereto.

Areas in which the plurality of light-emitting elements 120 is not disposed or the bank 110 is disposed may be the non-emission area NEA. The non-emission area NEA is an area disposed between the plurality of emission areas EA, and may be an area, in which the bank 110 is disposed. As an example, the non-emission area NEA is disposed to surround the plurality of emission areas EA, and thus may be formed in a mesh shape.

The dam 130 is disposed in the non-active area NA. For example, the dam 130 may be disposed on the substrate 101 in the non-active area NA. The dam 130 is disposed to control spreading of an organic encapsulation layer 152 of the encapsulation portion 150 disposed to cover the active area AA. For example, the dam 130 may reduce or suppress overflow of the organic encapsulation layer 152 of the encapsulation portion 150. One or more dams 130 may be configured, and the number of dams 130 to be deployed is not limited.

The pad portion 140 is disposed in the non-active area NA. The pad portion 140 may be disposed outside the dam 130. A signal may be input to a circuit, a circuit chip, etc., formed on the substrate 101 through the pad portion 140. For example, the pad portion 140 may supply a signal supplied from the outside to the circuit or the circuit chip of the substrate 101. For example, the pad portion 140 may supply a signal for driving the touch portion 160 to the touch portion 160, and may receive a signal for touch input of the user from the touch portion 160. For example, the pad portion may include a plurality of data pads, which are connected to the plurality of data lines through a plurality of data link lines, and a plurality of gate input pads which are connected to the gate driving circuit through a gate control signal line.

The encapsulation portion 150 is disposed on the light-emitting element 120. The encapsulation portion 150 is a sealing member for protection from external moisture, oxygen, impact, etc., to reduce or prevent oxidation of a light-emitting material and an electrode material of the light-emitting element 120. The encapsulation portion 150 may be disposed to cover the entire active area AA where the light-emitting element 120 is disposed, and the encapsulation portion 150 may cover a part of the non-active area NA extending from the active area AA. The encapsulation portion 150 may include a first inorganic encapsulation layer 151 made of an inorganic material, an organic encapsulation layer 152 made of an organic material and disposed on the first inorganic encapsulation layer 151, and a second inorganic encapsulation layer 153 disposed on the organic encapsulation layer 152.

An encapsulation portion may be formed on the substrate to surround the pixel array portion, and thus, may prevent oxygen or water from penetrating into the light emitting device layer of the pixel array portion. The encapsulation portion according to an embodiment of the present disclosure may be formed in a multi-layer structure where an organic material layer and an inorganic material layer are alternately stacked, but embodiments of the present disclosure are not limited thereto. The inorganic material layer may prevent oxygen or water from penetrating into the light emitting device layer of the pixel array portion. The organic material layer may be formed to have a thickness which is relatively thicker than that of the inorganic material layer, so as to cover particles occurring in a manufacturing process. For example, the encapsulation portion may include a first inorganic layer, an organic layer on the first inorganic layer, and a second inorganic layer on the organic layer. The organic layer may be a particle covering layer, but the terms are not limited thereto. A touch panel may be disposed on the encapsulation portion, or may be disposed on a rear surface of the pixel array portion or in the pixel array portion.

The first inorganic encapsulation layer 151 seals the active area AA to protect the light-emitting element 120 from oxygen and moisture penetrating into the active area AA. The first inorganic encapsulation layer 151 may be disposed not only in the active area AA, but also in the non-active area (NA) extending from the active area AA, and disposed to cover the dam 130 of the non-active area NA. The first inorganic encapsulation layer 151 is made of an inorganic material. For example, the first inorganic encapsulation layer 151 may be made of an inorganic material such as silicon nitride (SiNx), silicon oxide (SiOx), or silicon oxynitride (SiOxNy). However, the present disclosure is not limited thereto.

The organic encapsulation layer 152 is disposed on the first inorganic encapsulation layer 151. The organic encapsulation layer 152 is a layer for planarizing an upper part of the first inorganic encapsulation layer 151, fills a crack that may be generated in the first inorganic encapsulation layer 151, and/or may planarize an upper part of foreign matter when the foreign matter is formed on the first inorganic encapsulation layer 151. The organic encapsulation layer 152 may be disposed in the active area AA and up to a part of the non-active area NA extending from the active area AA, and may be disposed inside the dam 130. An epoxy-based or acrylic-based polymer may be used as the organic encapsulation layer 152. However, the present disclosure is not limited thereto.

The second inorganic encapsulation layer 153 is disposed on the organic encapsulation layer 152. The second inorganic encapsulation layer 153 may seal the organic encapsulation layer 152 together with the first inorganic encapsulation layer 151 by coming into contact with the first inorganic encapsulation layer 151 at an outer portion of the active area AA. The second inorganic encapsulation layer 153 may be disposed up to a part of the non-active area NA extending from the active area AA, and the second inorganic encapsulation layer 153 may be disposed to be in contact with the first inorganic encapsulation layer 151 disposed in the non-active area NA. The second inorganic encapsulation layer 153 is made of an inorganic material. For example, the second inorganic encapsulation layer 153 is made of an inorganic material such as silicon nitride (SiNx), silicon oxide (SiOx), or silicon oxynitride (SiOxNy). However, the present disclosure is not limited thereto.

FIG. 6 illustrates that the encapsulation portion 150 includes the first inorganic encapsulation layer 151, the organic encapsulation layer 152, and the second inorganic encapsulation layer 153. However, the number of inorganic encapsulation layers 151 and 153 and the number of organic encapsulation layers 152 included in the encapsulation portion 150 are not limited thereto.

The touch portion 160 may be optionally disposed on the encapsulation portion 150. The touch portion 160 may be disposed in the active area AA including the light-emitting element 120 to sense touch input. The touch portion 160 may detect external touch information using a finger of the user, a touch pen or other objects. The touch portion 160 may include a first protective layer 161, a second protective layer 162, an organic insulating layer 167, a first touch electrode 164, and a second touch electrode 165.

The first protective layer 161 may be disposed on the encapsulation portion 150. The first protective layer 161 may be in contact with and on the second inorganic encapsulation layer 153 of the encapsulation portion 150. The first protective layer 161 may be made of an inorganic material. For example, the first protective layer 161 may be made of an inorganic material such as silicon nitride (SiNx), silicon oxide (SiOx), or silicon oxynitride (SiOxNy), and the present disclosure is not limited thereto.

The first touch electrode 164 is disposed on the first protective layer 161. The first touch electrode 164 is disposed in the non-emission area NEA on the first protective layer 161. Respective first touch electrodes 164 may be spaced apart from each other and disposed in an X-axis direction and/or a Y-axis direction. For example, the first touch electrodes 164 may include a plurality of patterns spaced apart from each other disposed in the X-axis direction and a plurality of patterns spaced apart from each other disposed in the Y-axis direction. The first touch electrode 164 supplies a touch driving signal for driving the touch portion 160. In addition, the first touch electrode 164 may deliver touch information detected by the touch portion 160 to a driver IC. The first touch electrode 164 may have a mesh shape. However, the present disclosure is not limited thereto. The first touch electrode 164 may be made of a metal material. However, the present disclosure is not limited thereto.

The second protective layer 162 may be disposed on the first touch electrode 164 and the first protective layer 161. The second protective layer 162 may reduce or prevent short circuit of the adjacent first touch electrode 164.

The second touch electrode 165 may be disposed on the second protective layer 162. The second protective layer 162 may be made of an inorganic material. For example, the second protective layer 162 may be made of an inorganic material such as silicon nitride (SiNx), silicon oxide (SiOx), or silicon oxynitride (SiOxNy). However, the present disclosure is not limited thereto.

The pad portion 140 and the second touch electrode 165 may be electrically connected. As an example, the pad portion 140 and the second touch electrode 165 may be electrically connected to the flexible circuit film 400, for example, through a conductive adhesive layer 395. However, the present disclosure is not limited thereto.

FIG. 7 is a diagram for describing the display device according to an example embodiment of the present disclosure. A substantial configuration of FIG. 7 is the same as that of the display device of FIGS. 2 and 3, and thus a redundant description is omitted or briefly given.

A thickness of a component of the display device, for example, the cover member 10 tends to decrease so that the thickness of the display device decreases. As the thickness of the display device decreases, the display device may be sensitive to temperature changes, and the display device may be bent as illustrated in FIG. 7.

Since each of components of the cover member 10, the functional film 30, the display panel 100, and the plate 6 has a different contraction rate, expansion and contraction directions thereof at a high temperature may be different. For example, the functional film 30 may contract in a direction toward a center C of the display device, and the cover member 10, the display panel 100, and the plate 6 may expand toward an edge E of the display device. As an example, the center C may correspond to a region occupying 5%, 10%, 20%, 30%, etc., area at the center of the display device, and/or the edge E may correspond to a region occupying 5%, 10%, 20%, 30%, etc., area at the edge of the display device, or may correspond to a region of which the distance from the edge of the display device is less than 10 mm, 20 mm, 30 mm, 60 mm, 90 mm, etc.

Depending on the example embodiment of the present disclosure, for example, the display device for the vehicle may be frequently used in an environment in which temperature and humidity rapidly change. When the plate 6 of a single material is applied, a stress distribution may be different along a curved surface as illustrated in FIG. 7 due to a restoring force of the plate 6.

Since the plate 6 is made of a metal having excellent thermal conductivity and is relatively robust among the components of the display device, greatest stress may occur therein. When the temperature rises, for example, due to an operation of the display device and/or an external environment, contraction occurs more on a side where the temperature is high due to different cooling rates between the center C and the edge E, and thus defects may be generated due to a stress difference resulting from warping of the display device. Examples of the defects resulting from warping may include cracks in the display device and lifting of each component layer.

Thus, the inventors of the present disclosure have devised the display device, to which the plate 6 having a new structure is applied, capable of solving or mitigating the above-described problem or limitation caused by warping of the display device, for example, resulting from temperature changes.

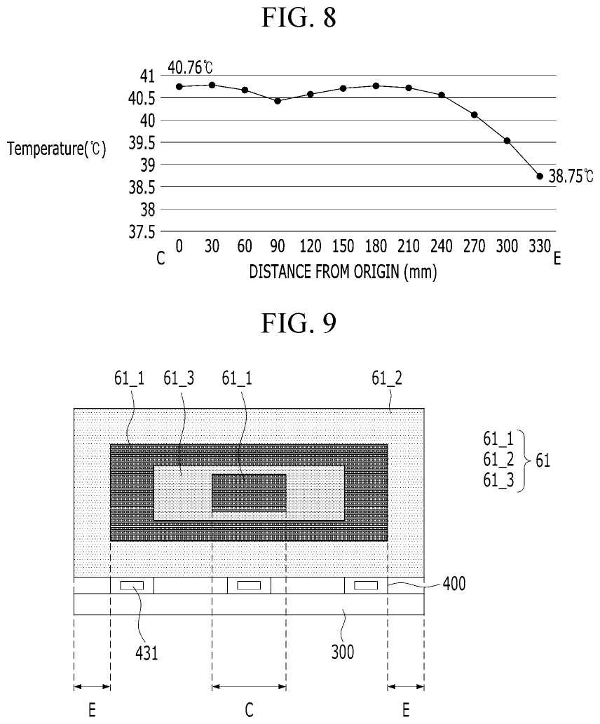

FIG. 8 is a diagram illustrating temperatures for describing temperature changes according to a comparative example of the present disclosure.

FIG. 8 is a diagram illustrating a result of simulating a temperature for each area of the display device in FIG. 7 according to a comparative example of the present disclosure. The inventors of the present disclosure simulated temperatures of the center C and the edge E from a lower surface of the plate 6 of FIG. 7.

Referring to FIGS. 7 and 8, it can be seen that the temperature of the display device according to the example embodiment of the present disclosure is different for each position and area.

According to the comparative example of the present disclosure, a temperature of the center C is a temperature of a point where a distance from a center origin of the lower surface of the plate 6 is 0 mm.

According to the comparative example of the present disclosure, a temperature of the edge E is a temperature of a point where a distance from the center origin of the lower surface of the plate 6 is 330 mm.

It can be seen that the temperature of the center C was 40.76° C. and the temperature of edge E was 38.75° C., indicating a temperature difference of 2.01° C. At the center C of the display device, the driving circuit for driving the display panel of the display device and the at least one circuit chip 431 may be disposed, so that heat is generated and the temperature rises. Further, the edge E is spaced apart from the at least one circuit chip 431, and thus may have a low temperature increase rate, so that a temperature difference with the center C may occur. A temperature difference for each position of the display device may cause warping due to a stress difference for each position of the display device. Reliability of the display device may be a limitation or a problem. For example, when exposed to a high-temperature environment as the display device for the vehicle, a larger temperature difference may occur, and warping improvement may be beneficial.

FIG. 9 is a plan view according to an example embodiment of the present disclosure. FIG. 9 may be, for example, a plan view from the lower surface of the plate 60 in FIG. 10. The at least one circuit chip 431 may be a source driver integrated circuit (IC). Each of the at least one circuit chip 431 may be mounted on the flexible circuit film 400 using a COF or COP method. The flexible circuit film 400 is attached to pads provided in the non-active area of the display panel 100 using, for example, an anisotropic conductive film, whereby the at least one circuit chip 431 may be attached to the pads. The printed circuit board 300 may be attached to the flexible circuit films 400. A plurality of circuits implemented as driving chips may be mounted on the printed circuit board 300.

FIG. 10 is a cross-sectional view according to an example embodiment of the present disclosure.

A substantial configuration of FIG. 10 is the same as that of the display device of FIGS. 2 and 3 except for a coated layer 61 of the plate 60, and thus a redundant description is omitted or briefly given.

Referring to FIGS. 9 and 10, the plate 60 of the display device according to the example embodiment of the present disclosure uses a heat dissipating member as a base layer 60a. As an example, the plate 60 of the display device may use a heat dissipating metal such as aluminum or an aluminum alloy, etc., as a base layer 60a, and may include a coated layer 61 on a surface of the base layer 60a. The coated layer 61 may be included on at least one surface of the plate 60. For example, as illustrated in FIG. 10, the coated layer 61 may be coated with both a first coated layer 61a and a second coated layer 61b on an upper surface and a lower surface of the base layer 60a, respectively. For example, any one of the upper surface and the lower surface of the base layer 60a may be coated. The embodiments of the present disclosure are not limited thereto. It should be understood that “coated” includes the meaning of deposited, formed, adhered, and the like, and does not require an action of coating be performed. The term “coated” also includes the meanings of partially coated and fully coated. For example, the coated layer 61 may be deposited by any appropriate method, and may partially cover the plate 60. The term “coated layer” does not require that the coated layer 61 be coated by something else. Namely, the coated layer 61 may “coat” the plate 60 without itself being coated by another material or layer.

The base layer 60a having a heat-dissipating member (e.g., a heat-dissipating metal component), which is a core layer of the plate 60, may support the display panel 100, which, for example, may have high warping properties.

In the plate 60, the coated layer 61 on at least one surface of the plate 60 is coated to have a black color so that heat (e.g., due to driving of the display device and/or the external environment) is absorbed from a lower side, and heat may be dissipated to reduce or prevent temperature rise of the display panel 100 and the display device. For example, the base layer 60a may be configured to be thicker than the display panel 100 to have a support function and a heat dissipation function. The base layer 60a may have a thickness of 0.2 mm or more and 1 mm or less. The embodiments of the present disclosure are not limited thereto. As an example, the thickness of the base layer 60a may be the same as or even smaller than that of the display panel 100, and/or may be smaller than 0.2 mm or greater that 1 mm.

The coated layer 61 may be thinner than the base layer 60a. The coated layer 61 may have a thickness of, for example, 10 μm or more and less than 0.1 mm. The embodiments of the present disclosure are not limited thereto. As an example, the thickness of the coated layer 61 may be the same as or even greater than the base layer 60a.

The coated layer 61 may include a material having high emissivity. As an example, the coated layer 61 may include a material having higher emissivity than the base layer 60a or the display panel 100. Emissivity is a rate at which energy is emitted from a material. Emissivity refers to efficiency of energy dissipation from a surface of an object in the event of thermal radiation. For example, emissivity is a ratio of energy emitted to the outside by a material containing energy of 1. Theoretically, an object that only absorbs energy and does not emit energy is called a blackbody, and emissivity thereof is defined as 1. Emissivity is a ratio of radiant energy emitted from a real surface to radiant energy emitted from a blackbody at the same temperature. An emissivity value of an object at room temperature may be expressed as a value of 0 (100% reflection) to 1 (100% absorption) by measuring a degree to which glass reflects infrared energy in a long wavelength region. The coated layer 61 may be a material having high emissivity. As a color is closer to black, more energy is absorbed, and thus emissivity may be higher, and heat dissipation effect may be higher. For example, as black concentration increases, emissivity may increase, and heat dissipation effect may increase. The coated layer 61 may be made of a material such as black resin. The coated layer 61 may include black pigment. The coated layer 61 may include at least one of graphite powder, alumina, boron nitride, aluminum nitride, carbon black, or copper chromite black spinel, etc., for heat dissipation. The coated layer 61 may not only absorb residual light but also reduce or prevent light on the rear side of the plate 60 from being viewed.

According to an example embodiment of the present disclosure, referring to FIG. 9, at least one circuit chip 431 may be placed on the flexible circuit film 400. FIG. 9 illustrates that each of the number of the at least one circuit chip 431 and the number of flexible circuit films 400 is three. However, this is only an example embodiment of the present disclosure, and the number of the at least one circuit chip 431 and the number of flexible circuit films 400 are not limited to the embodiments of the present disclosure.

According to an example embodiment of the present disclosure, emissivity of the coated layer 61 may be differently disposed for each region of the plate 60 in order to improve warpage of the display device by minimizing a temperature difference between regions of the display device.

A first region 61_1 of the coated layer 61 may be a region overlapping the circuit chip 431 on the plate 60. The first region 61_1 of the coated layer 61 may be a region overlapping the flexible circuit film 400. The first region 61_1 of the coated layer 61 may be a region located at the center C of the plate 60. A second region 61_2 of the coated layer 61 may be a region at the edge E of the plate 60. The third region 61_3 of the coated layer 61 may be a region between a plurality of adjacent first regions 61_1. Although it is illustrated in FIG. 9 that there are two first regions 61_1 in the coated layer 61, there could be more than two first regions 61_1 in the coated layer 61 separated from each other. In addition, although it is illustrated in FIG. 9 that the first regions 61_1 may have a rectangular shape, the embodiments are not limited thereto. As an example, as long as the first region 61_1 corresponds to at least one of the circuit chip 431, flexible circuit film 400 or the center C of the plate 60, the first regions 61_1 could have any shape such as a square shape, a trapezoid shape, a circular shape, an oval shape, etc.

The center C and the first region 61_1, which are regions overlapping the circuit chip 431 and the flexible circuit film 400, may be regions in which a lot of heat is generated due to circuit driving, and thus emissivity of the coated layer 61 may be increased. Heat of the circuit chip 431 and the flexible circuit film 400 may be absorbed by increasing emissivity of the coated layer 61. In order to increase emissivity, black concentration of the first region 61_1 of the coated layer 61 of the plate 60 may be increased. The coated layer 61 may have different emissivity for each of the first region 61_1, the second region 61_2, and the third region 61_3. The coated layer 61 may have different black concentration for each of the first region 61_1, the second region 61_2, and the third region 61_3. The coated layer 61 may have a difference in content of at least one of graphite powder, carbon black, or copper chromite black spinel, which controls concentration of black for each of the first to third regions 61_1, 61_2, and 61_3. In addition, as an example, the first region 61_1 located at the center C of the plate 60 and the first region 61_1 overlapping the circuit chip 431 or the flexible circuit film 400 may have the same or different emissivity and the same or different black concentration.

For example, copper chromite black spinel exhibiting a black color may be included in black pigment. For example, black concentration and emissivity may be increased by increasing content of copper chromite black spinel included in black pigment.

The edge E and the second region 61_2, which are regions not overlapping the circuit chip 431 and the flexible circuit film 400, are regions having relatively low temperatures, and thus emissivity of the coated layer 61 may be lower therein than in the first region 61_1. It should be understood that the second region 61_2 may include portions that do not overlap the circuit chip 431 and the flexible circuit film 400 while also including portions that do overlap the said elements. For example, as depicted in FIG. 9, relative to the page, vertical portions of the second region 61_2 may be aligned with and overlap the edge E, whereas horizontal portions of the second region 61_2 that are between the vertical portions may overlap the circuit chip 431 and the flexible circuit film 400.

The first region 61_1 and the second region 61_2 of the coated layer 61 may have different emissivities. The first region 61_1 and the third region 61_3 of the coated layer 61 may have different emissivities.

The first region 61_1 and the second region 61_2 of the coated layer 61 may have different black concentrations. The first region 61_1 and the third region 61_3 of the coated layer 61 may have different black concentrations.

The emissivity of the first region 61_1 of the coated layer 61 may be higher than that of the second region 61_2 of the coated layer 61.

The black concentration of the first region 61_1 of the coated layer 61 may be higher than that of the second region 61_2 of the coated layer 61.

Even though the third region 61_3 of the coated layer 61 does not overlap with the circuit chip 431 and the flexible circuit film 400, the third region 61_3 is located between a plurality of first regions 61_1, which are regions overlapping the circuit chip 431 and the flexible circuit film 400. Thus, the third region 61_3 may be affected by temperature rise, and thus may have a higher temperature than that of the edge E.

The emissivity of the third region 61_3 of the coated layer 61 may be higher than that of the second region 61_2 of the coated layer 61, without being limited thereto. As another example, the emissivity of the third region 61_3 of the coated layer 61 may be equal to or even lower than that of the second region 61_2 of the coated layer 61.

The black concentration of the third region 61_3 of the coated layer 61 may be higher than that of the second region 61_2 of the coated layer 61, without being limited thereto. As another example, the black concentration of the third region 61_3 of the coated layer 61 may be equal to or even lower than that of the second region 61_2 of the coated layer 61.

The emissivity of the first region 61_1 of the coated layer 61 may be higher than that of the third region 61_3 of the coated layer 61.

The black concentration of the first region 61_1 of the coated layer 61 may be higher than that of the third region 61_3 of the coated layer 61.

The emissivity of the center C of the coated layer 61 may be higher than the emissivity of the edge E of the coated layer 61.

The black concentration of the center C of the coated layer 61 may be higher than the black concentration of the edge E of the coated layer 61.

According to an example embodiment of the present disclosure, for example, the emissivity of the first region 61_1 of the coated layer 61 may be 0.7 to 0.9, or 0.8 to 0.9, the emissivity of the second region 61_2 of the coated layer 61 may be 0 to 0.2, 0 to 0.4 or 0 to 0.6, and the emissivity of the third region 61_3 of the coated layer 61 may be 0.6 to 0.8, or 0.7 to 0.8, without being limited thereto. As an example, the emissivity of the first region 61_1, the second region 61_2 and the third region 61_3 of the coated layer 61 may be any value between 0 to 1, as long as the emissivity of the first region 61_1 is higher than that of the second region 61_2 and the third region 61_3.

According to an example embodiment of the present disclosure, for example, the black concentration of the first region 61_1 of the coated layer 61 may be 9% to 12%, or 10% to 12%, the black concentration of the second region 61_2 of the coated layer 61 may be 0% to 4%, or 0% to 7%, and the black concentration of the third region 61_3 of the coated layer 61 may be 4% to 7%, or 7% to 9%, without being limited thereto. As an example, the black concentration of the first region 61_1, the second region 61_2 and the third region 61_3 of the coated layer 61 may be any value between 0% to 100%, as long as the black concentration of the first region 61_1 is higher than that of the second region 61_2 and the third region 61_3.

Any one or more of the coating area, emissivity, and black concentration for each coating region of the coated layer 61 may be different depending on the positions of the circuit chip 431 and the flexible circuit film 400, and the embodiments of the present disclosure are not limited thereto.

According to an example embodiment of the present disclosure, when the emissivity of the center C or the first region 61_1 is set to be higher than that of the edge E or the second region 61_2 of the coated layer 61, a temperature difference for each position of the plate 60 may be improved when compared to the case where the emissivity is set to be the same on the entire surface of the coated layer 61. When the emissivity of the center C and the first region 61_1 of the coated layer 61 increases, the increased temperature rapidly decreases, and when the emissivity of the edge E and the second region 61_2 of the coated layer 61 decreases, cooling slowly progresses at a low temperature, so that a cooling rate becomes the same in the entire region. Therefore, a temperature difference may be reduced or prevented, and warping of the display device may be improved. By reducing or preventing warping, cracks and lifting between layers due to internal stress of the display device may be reduced or prevented, thereby improving reliability. By improving the temperature difference to improve warping, the thickness of the display device including the cover member 10 may be improved.

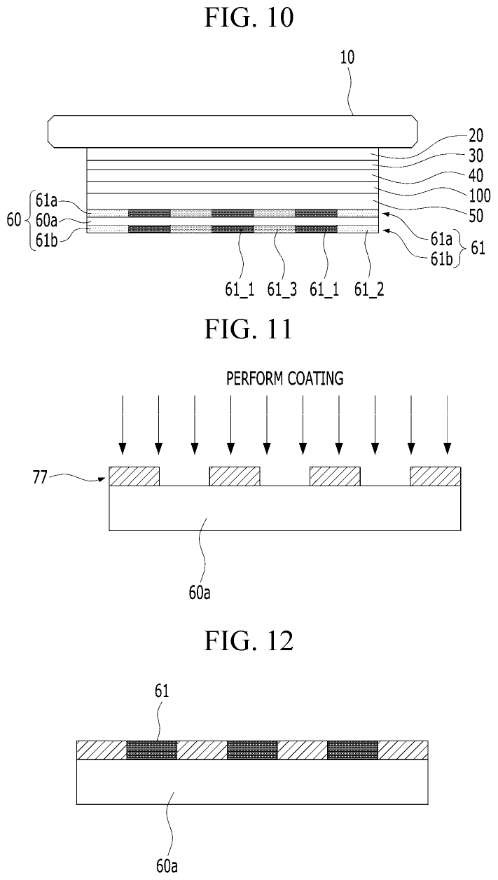

FIGS. 11, 12, and 13 are views illustrating processes according to an example embodiment of the present disclosure.

The manufacturing processes will be described. After the base layer 60a of the plate 60 is molded in units of unit base layers 60a according to a size beneficial for the display device, the coated layer 61 may be formed on a surface of the base layer 60a.

Referring to FIG. 11, a sheet 77 is attached in a predetermined or selected pattern onto the base layer 60a to define or mask a portion where the coated layer 61 is not formed. Thereafter, a region where the sheet paper 77 exposes the base layer 60a may be coated with a material used for coating, for example, a coating material including black pigment.

Referring to FIG. 12, the coated layer 61 may be disposed on a part where the sheet paper 77 is not formed, for example, a region to be partially coated, and then cured.

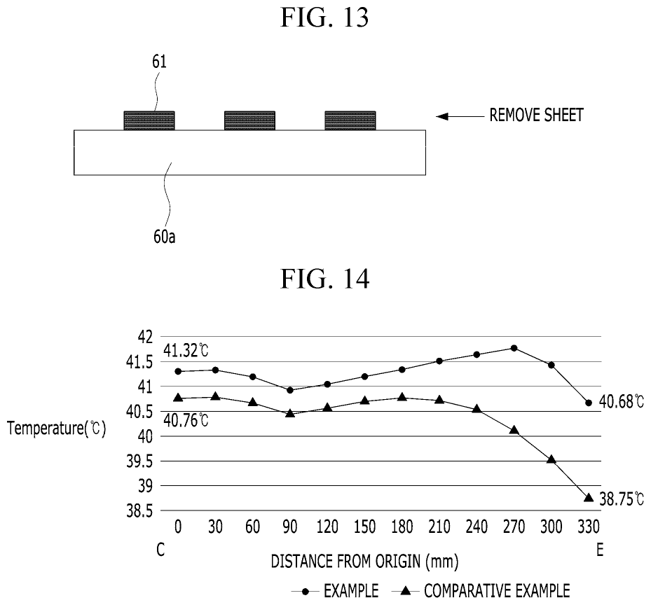

Referring to FIG. 13, when the sheet paper 77 is removed, the coated layer 61 is selectively left only in a desired or selected region on the base layer 60a.

A first region 60_1 may be formed on the plate 60 in the manner of FIGS. 11 to 13, and a second region 60_2 and a third region 60_3 may be sequentially formed in the same manner. In some cases, the second region 60_2 and the third region 60_3 may be formed in the same process.

A configuration order of the first region 60_1, the second region 60_2, and the third region 60_3 may be different from that described above. For example, the second region 60_2 or the third region 60_3 may be formed before the first region 60_1. The embodiments of the present disclosure are not limited thereto.

The second region 60_2 and the third region 60_3 may have black concentration different from that of the first region 60_1, so that a region of the coated layer having different black concentration and/or emissivity may be configured.

FIG. 14 is a diagram illustrating temperature according to an example embodiment of the present disclosure. FIG. 14 is a diagram illustrating simulation results of temperatures for each region of the display device according to a comparative example and an example of the present disclosure. The inventors of the present disclosure simulated the temperatures of the center C and the edge E from the lower surface of the plate 60 of FIG. 10 as an example. The inventors of the present disclosure simulated the temperatures of the center C and the edge E from the lower surface of the plate 60 of FIG. 7 as a comparative example.

Table 1 below shows the temperatures of the content illustrated in FIG. 14.

TABLE 1

| | Temperature | Temperature | Temperature |
|---|---|---|---|
| | of center C | of edge E | difference |
| Item | (° C.) | (° C.) | (° C.) |
| Comparative example | 40.76 | 38.75 | 2.01 |
| Example | 41.32 | 40.68 | 0.64 |

Referring to Table 1 and FIG. 14, it can be seen that the temperature is different for each position and region of the display device according to the comparative example of the present disclosure.

According to the comparative example and the example of the present disclosure, the temperature of the center C is a temperature at a point where the distance from the center origin of the lower surface of the plate 60 is 0 mm.

According to the comparative example and the example of the present disclosure, the temperature of the edge E is a temperature at a point where the distance from the center origin of the lower surface of the plate 60 is 330 mm.

It can be seen that the temperature of the center C of the display device according to the comparative example of the present disclosure was 40.76° C., and the temperature of the edge E thereof was 38.75° C., indicating that a temperature difference of 2.01° C. occurs.

It can be seen that the temperature of the center C of the display device according to the example of the present disclosure was 41.32° C., and the temperature of the edge E thereof was 40.68° C., indicating that a temperature difference of 0.64° C. occurs.

It can be confirmed that the temperature difference for each position and region of the display device according to the example the present disclosure is improved. It can be seen that improvement is about 70% when compared to the temperature difference of the display device according to the comparative example of the present disclosure.

It can be seen that the temperature difference between the center C and the edge E is improved by setting emissivity of the coated layer 61 of the display device according to the example embodiment of the present disclosure to be different for each coating region so that the temperatures of the plate 60 and the display device are evenly distributed. By improving the temperature difference for each region, warping due to the stress difference of the display device may be reduced or prevented. Reliability and quality may be improved by improving warping.

The display device according to the example embodiments of the present disclosure may be applied to a mobile device, a videophone, a smartwatch, a watchphone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, navigation, vehicle navigation, a vehicle display device, a vehicle device, a theater device, a theater display device, a television, a wallpaper device, a signage device, a game device, a notebook, a monitor, a camera, a camcorder, a home appliance, etc. In addition, the display device of the present disclosure may be applied to an organic light-emitting illumination device or an inorganic light-emitting illumination device.

The display device according to the example embodiment of the present disclosure may include a plate, a display panel provided on the plate, at least one circuit chip provided on one side of the display panel, and a coated layer on at least one surface of the plate. The coated layer includes a first region overlapping the at least one circuit chip and a second region at an edge of the plate, and black concentration of the first region may be different from that of the second region.

According to some embodiments of the present disclosure, the black concentration of the first region may be higher than that of the second region.

According to some embodiments of the present disclosure, the first region and the second region may have different emissivities.

According to some embodiments of the present disclosure, the emissivity of the first region may be higher than the emissivity of the second region.

According to some embodiments of the present disclosure, the at least one circuit chip may be placed disposed on a flexible circuit film.

According to some embodiments of the present disclosure, the coated layer includes a plurality of first regions adjacent to each other and a third region between the plurality of first regions.

Black concentration of the third region may be different from the black concentration of each first region.

According to some embodiments of the present disclosure, the black concentration of the third region may be lower than the black concentration of the each first region.

According to some embodiments of the present disclosure, the coated layer may be disposed on each of an upper surface of the plate and a lower surface of the plate.

According to some embodiments of the present disclosure, the coated layer may include black pigment.

According to some embodiments of the present disclosure, the coated layer may include copper chromite black spinel.

According to some embodiments of the present disclosure, the display panel may further include an encapsulation portion and a touch portion.

According to some embodiments of the present disclosure, a cover member may be disposed on the display panel.

The display device according to the example embodiment of the present disclosure may include a plate, a display panel provided on the plate and a coated layer on at least one surface of the plate, wherein the plate may comprise a center region and an edge region, and wherein black concentration of the coated layer located in the center region may be different from black concentration of the coated layer located in the edge region.

According to some embodiments of the present disclosure, the black concentration of the coated layer located in the center region may be higher than the black concentration of the coated layer located in the edge region.

According to some embodiments of the present disclosure, emissivity of the coated layer located in the center region may be higher than emissivity of the coated layer located in the edge region.

According to some embodiments of the present disclosure, the display panel may further comprise at least one circuit chip and a flexible circuit film connecting the at least one circuit chip.

According to some embodiments of the present disclosure, at least one of a coating area, emissivity, or and black concentration for each region of the coated layer may be different according to locations of the at least one circuit chip and the flexible circuit film.

The display device according to the example embodiment of the present disclosure may include a plate, a display panel provided on the plate, at least one circuit chip provided on a side of the display panel and a coated layer on at least one surface of the plate, wherein the coated layer may comprise a first region overlapping at least one circuit chip and a second region at an edge of the plate, and wherein emissivity of the first region may be different from emissivity of the second region.

According to some embodiments of the present disclosure, the emissivity of the first region may be higher than the emissivity of the second region.

According to some embodiments of the present disclosure, the at least one circuit chip may be provided disposed on a flexible circuit film.

According to the example embodiments of the present disclosure, since warping of the display device may be improved by differently disposing the coated layer of the plate applied to the display device for each region of the display device, cracks and lifting between layers due to internal stress may be prevented, so that performance and/or reliability of the display device may be improved.

According to the example embodiments of the present disclosure, the display device having improved warping may be provided by optimizing the coated layer applied to the display device according to a region of the display device.

According to the example embodiments of the present disclosure, the display device having improved temperature change may be provided by providing the coated layer of the display device having different emissivities per region of the display device.

According to the example embodiments of the present disclosure, by applying the coated layer selected for temperature changes to the display device, warping may be improved, and thus the display device having a reduced thickness may be provided.

Effects of the present disclosure are not limited to the effects mentioned above, and other effects not mentioned will be clearly understood by those skilled in the art from the above description.

Since content of the disclosure described in the problems to be solved, the means for solving the problems, and the effects above do not specify the essential features of the claims, the scope of the claims is not limited by the matters described in the content of the disclosure.

Even though the example embodiments of the present disclosure have been described in more detail with reference to the accompanying drawings, the present disclosure is not necessarily limited to these embodiments, and may be variously modified and implemented without departing from the technical spirit of the present disclosure. Therefore, the example embodiments disclosed in the present disclosure are not intended to limit the technical spirit of the present disclosure, but to describe the technical spirit, and the scope of the technical spirit of the present disclosure is not limited by these embodiments. Therefore, the example embodiments described above should be understood as illustrative in all respects and not restrictive.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a plate;
a display panel on the plate;
at least one circuit chip connected to a side of the display panel; and
a coated layer on at least one surface of the plate,
wherein the coated layer includes a first region overlapping the at least one circuit chip and a second region not overlapping the at least one circuit chip, and
wherein a first black concentration of the first region is different from a second black concentration of the second region.

2. The display device according to claim 1, wherein the first black concentration of the first region is higher than the second black concentration of the second region.

3. The display device according to claim 1, wherein emissivity of the second region is different from emissivity of the first region.

4. The display device according to claim 3, wherein the emissivity of the first region is higher than the emissivity of the second region.

5. The display device according to claim 1, wherein the at least one circuit chip is disposed on a flexible circuit film attached to the side of the display panel.

6. The display device according to claim 1, wherein the second region is located at an edge of the plate, or between adjacent first regions.

7. The display device according to claim 1, wherein:
the second region is located at an edge of the plate,
the coated layer includes a plurality of first regions adjacent to each other;
the coated layer further includes a third region between the plurality of first regions; and
a third black concentration of the third region is different from the black concentration of each of the first and second regions.

8. The display device according to claim 7, wherein the third black concentration of the third region is lower than the first and second black concentration of each of the first and second regions.

9. The display device according to claim 7, wherein the third black concentration of the third region is higher than the second black concentration of the second region.

10. The display device according to claim 1, wherein the coated layer is disposed on each of an upper surface of the plate and a lower surface of the plate.

11. The display device according to claim 1, wherein the coated layer includes black pigment.

12. The display device according to claim 1, wherein the coated layer includes copper chromite black spinel.

13. The display device according to claim 1, wherein the display panel further includes an encapsulation portion and a touch portion.

14. The display device according to claim 1, further comprising a cover member on the display panel.

15. The display device according to claim 1, wherein the at least one circuit chip is at least one of a scan driver, a data driver and a touch driver of the display device.

16. The display device according to claim 1, wherein the coated layer includes a material having higher emissivity than the plate.

17. The display device according to claim 1, wherein the first black concentration of the first region is in a range of 10% to 12%, and the second black concentration of the second region is in a range of 0% to 4% or in a range of 7% to 9%.

18. The display device according to claim 1, wherein the coated layer further includes a third region at a center of the plate, and
Wherein the first black concentration of the first region is the same as the third black concentration of the third region.

19. A display device, comprising:
a plate;
a display panel on the plate; and
a coated layer on at least one surface of the plate, wherein:
the plate includes a center region and an edge region; and
a center black concentration of the coated layer located in the center region is different from an edge black concentration of the coated layer located in the edge region.

20. The display device according to claim 19, wherein the center black concentration of the coated layer located in the center region is higher than the edge black concentration of the coated layer located in the edge region.

21. The display device according to claim 19, wherein emissivity of the coated layer located in the center region is higher than emissivity of the coated layer located in the edge region.

22. The display device according to claim 19, further comprising at least one circuit chip and a flexible circuit film connecting the at least one circuit chip to the display panel.

23. The display device according to claim 19, wherein the coated layer is positioned on each of an upper surface of the plate and a lower surface of the plate.

24. The display device according to claim 22, wherein at least one of a coating area, emissivity and black concentration for each region of the coated layer is different according to locations of the at least one circuit chip and the flexible circuit film.

25. A display device, comprising:
a plate;
a display panel on the plate;
at least one circuit chip connected to a side of the display panel; and
a coated layer on at least one surface of the plate, wherein:
the coated layer includes a first region overlapping the at least one circuit chip and a second region not overlapping the at least one circuit chip; and
wherein emissivity of the first region is different from emissivity of the second region.

26. The display device according to claim 25, wherein the emissivity of the first region is higher than the emissivity of the second region.

27. The display device according to claim 25, wherein the at least one circuit chip is disposed on a flexible circuit film attached to the display panel.

28. A display device, comprising:
a plate;
a display panel on the plate; and
a coated layer on at least one surface of the plate, wherein:
the plate includes a first region and a second region; and
first black concentration of the coated layer located in the first region is higher than second black concentration of the coated layer located in the second region.

29. The display device according to claim 28, wherein the first region corresponds to at least one of a center region of the plate, a region overlapping at least one circuit chip connected to a side of the display panel and a region overlapping a flexible circuit film connecting the at least one circuit chip to the display panel, and the second region corresponds to area of the plate other than the first region.

30. A display device, comprising:
a plate;
a display panel on a first side of the plate;
a circuit chip connected to the display panel and positioned on a second side of the plate; and
a resin layer on at least one surface of the plate, the resin layer including a first region corresponding to the circuit chip and a second region adjacent the first region, the first region having emissivity that exceeds that of the second region.

31. The display device of claim 30, further comprising:
a guide panel on the second side of the plate; and
a flexible circuit film having the circuit chip positioned thereon, the flexible circuit film wrapping around the plate and the guide panel.
